(19) United States
(12) Patent Application Publication
(10) Pub. No.: US 2020/0410363 A1
(43) Pub. Date: Dec. 31, 2020

(54) ABNORMALITY DETECTION SYSTEM AND ABNORMALITY DETECTION PROGRAM

(71) Applicant: RENESAS ELECTRONICS CORPORATION, Tokyo (JP)

(72) Inventor: Masatoshi KAWATAKE, Tokyo (JP)

(21) Appl. No.: 16/855,763

(22) Filed: Apr. 22, 2020

(30) Foreign Application Priority Data
Jun. 28, 2019 (JP) 2019-121438

(51) Int. Cl. G06N 3/08; G06N 3/04; H01L 21/67

(52) U.S. Cl. CPC G06N 3/088; G06N 3/0481; H01L 21/67253; G06N 3/04

(57) ABSTRACT

An abnormality detection system has a detection target waveform generation unit and a detection target waveform determination/abnormality detection unit. The detection target waveform includes a target waveform detection algorithm learning the detection target waveform and generates an expected detection target waveform by executing the target waveform detection algorithm for an input waveform. The detection target waveform determination/abnormality detection unit compares the expected detection target waveform with the input waveform to determine that the input waveform corresponds to the detection target waveform.

### CROSS-REFERENCE TO RELATED APPLICATIONS

The disclosure of Japanese Patent Application No. 2019-121438 filed on Jun. 28, 2019 including the specification, drawings and abstract is incorporated herein by reference in its entirety.

### BACKGROUND

The present invention relates to an abnormality detection system and an abnormality detection program, for example, to an abnormality detection system and an abnormality detection program of a manufacturing apparatus in a manufacturing plant of semiconductors or the like.

For example, in an abnormality detection system for a manufacturing apparatus in a manufacturing plant such as semiconductors, the signal to be detected is separated and extracted as a trigger condition when a certain condition is satisfied, such as when the input signal level exceeds a predetermined value.

There is disclosed techniques listed below.

### [Patent Document 1]

Japanese unexamined Patent Application Publication No. 2010-38884

In addition to the input signal levels, Patent Document 1 discloses a method for separating the signal to be detected by using input signal rise/fall times, setup/hold violations, runts, transitions, pulse widths, and the like as triggers.

### SUMMARY

As in the detection method of Patent Document 1, when waveforms satisfying the conditions for separating the detection object are mixed in addition to detection target waveform to be detected, there were cases in which a judgment was made for the waveform that is incorrectly regarded as the detection target waveform.

Other objects and novel features will become apparent from the description of this specification and the accompanying drawings.

According to one embodiment, the abnormality detection system includes a detection target waveform generating unit that has an target waveform detection algorithm learning a detection target waveform and generates an expected detection target waveform by executing the target waveform detection algorithm for an input waveform to output the expected detection target waveform generated, and a detection target waveform determination and abnormality detection unit that compares the expected detection target waveform with the input waveform and to determine that the input waveform corresponds to the detection target waveform.

According to the one embodiment, in addition to detection target waveform to be detected, even when the waveforms satisfying the conditions for separating the detection object are mixed, it is possible to recognize the detection target waveform, further, it is possible to provide an abnormality detection system and an abnormality detection program capable of detecting an abnormality of the detection target waveform.

### BRIEF DESCRIPTION OF THE DRAWINGS

FIG. 1 is a block diagram illustrating an example of the abnormality detection system according to the first embodiment.

FIG. 2 is a flowchart illustrating an example of the processes of the detection target waveform generation unit in the abnormality detection system according to the first embodiment.

FIG. 3 is a diagram illustrating an example of the detection target waveform of the abnormality detection system according to the first embodiment.

FIG. 4 is a diagram illustrating an example of data of detection target waveform of the abnormality detection system according to first embodiment.

FIG. 5 is a diagram illustrating a perceptron representing the configuration of an autoencoder, which is one of the techniques of deep learning used by detection target waveform generation unit, in the abnormality detection system according to the present embodiment.

FIG. 6 is a diagram illustrating a learning data for a deep learning that is set to the target waveform detection algorithm in the abnormality detection system of the first embodiment.

FIG. 7 is a flow chart illustrating an example of the processes of detection target waveform determination/abnormality detection unit in the abnormality detection system according to the first embodiment.

FIG. 8 is a diagram illustrating detection target waveform input to the detection target waveform determination/abnormality detection unit in the abnormality detection system according to the first embodiment.

FIG. 9 is a diagram illustrating an input signal including an input waveform that is not a detection target waveform input to the detection target waveform determination/abnormality detection unit in the abnormality detection system according to the first embodiment.

FIG. 10 is a diagram of an input signal, similar to detection target waveform, but with some distorted input waveforms, in the abnormality detection system according to the first embodiment.

FIG. 11 is a configuration diagram illustrating the abnormality detection system according to the second embodiment.

FIG. 12 is a flow chart illustrating the processes of the detection target waveform determination unit in the abnormality detection system according to the second embodiment.

FIG. 13 is a flow chart illustrating the processes of detection target waveform generation unit in the abnormality detection system according to the second embodiment.

FIG. 14 is a flow chart illustrating the processes of the abnormality detection unit in the abnormality detection system according to the second embodiment.

FIG. 15 is a block diagram illustrating the abnormality detection system according to the third embodiment.

FIG. 16A is a timing chart showing the monitor signal based on the operation of manufacturing system according to the third embodiment.

FIG. 16B is a timing chart showing a likelihood and a display of abnormality display unit based on the operation of the manufacturing system according to third embodiment.

### DETAILED DESCRIPTION

For clarity of explanation, the following description and drawings are appropriately omitted and simplified. In the drawings, the same elements are denoted by the same reference numerals, and a repetitive description thereof is omitted as necessary.

### First Embodiment

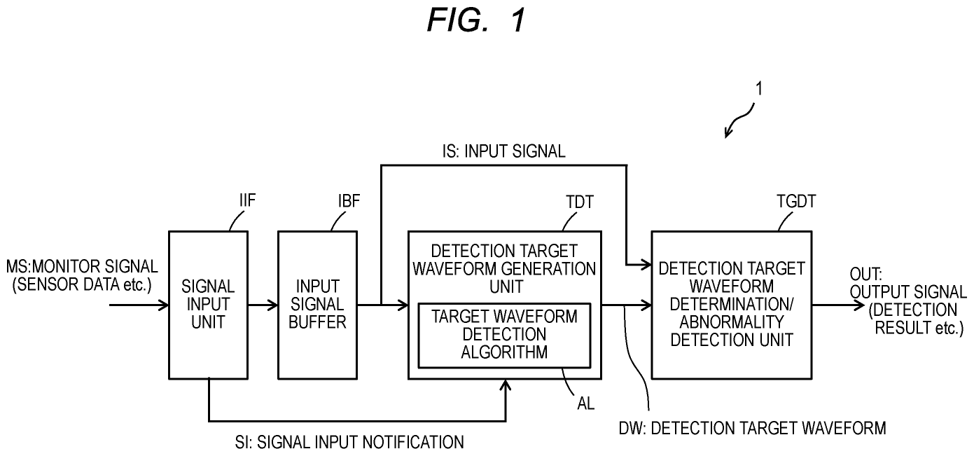

The abnormality detection system according to first embodiment will be described. FIG. 1 is a block diagram illustrating an abnormality detection system 1 according to the first embodiment. As shown in FIG. 1, the abnormality detection system 1 includes a signal input unit IIF, an input signal buffer IBF, a detection target waveform generation unit TDT, and a detection target waveform determination/abnormality detection unit TGDT. The abnormality detection system 1 of the present embodiment is, for example, a device for detecting an abnormality of the semiconductor manufacturing apparatus in semiconductor device manufacturing system. However, the present invention is not necessarily limited to this, and the abnormality detection system can be applied as a device for detecting abnormalities of various manufacturing apparatus in various manufacturing systems.

A signal input unit IIF receives the monitor signals MS from the detection target apparatus. The monitor signal MS is, for example, a signal representing the status of the process of the manufacturing apparatus. The monitor signal MS is sensor data or the like and is a sensor signal from various sensors provided in the manufacturing apparatus or added to the manufacturing apparatus. Various sensors, for example, a flow sensor for monitoring the flow rate of the gas, a pressure sensor for monitoring the pressure of the chamber, a power sensor for monitoring the RF power of the plasma, or an EPD (End Point Detector) for monitoring the progress of etching, but not limited to these, other, may be various.

In semiconductor device manufacturing systems, transmission and reception of sensor signals between apparatuses can be accomplished using communication protocols called SECS (SEMI Equipment Communications Standard). RS232C or Ethernet is used as the physical interfaces of SECS. The signal input unit IIF may, for example, be used as such SECS communication interfaces. The signal input unit IIF receives sensor signals transmitted, for example, from the sensors using SECS.

The signal input unit IIF performs predetermined signal processing on the received monitor signal MS. For example, signal input unit IIF may include an analog-to-digital converter and the like. In this situation, the signal input unit IIF directly receives an analog signal from the sensor as the monitor signal MS without using SECS, and converts it into a digital signal. The signal input unit IIF transmits a monitor signal MS having performed a predetermined signal processing to the input signal buffer IBF.

The input signal buffer IBF holds the monitor signal MS outputted from the signal input unit IIF for a predetermined period by using a ring buffer or the like. By holding the monitor signal MS for the predetermined period, it can be an input signal IS including the input waveform. The input signal buffer IBF outputs the held monitor signal MS as an input signal IS including the input waveforms to the detection target waveform generation unit TDT and the detection target waveform determination/abnormality detection unit TGDT.

The detection target waveform generation unit TDT has a target waveform detection algorithm AL. The target waveform detection algorithm AL, for example, has been learned the detection target waveform TW (not shown). By using the target waveform detection algorithm AL, the expected detection target waveform DW is generated based on the input waveform contained in the input signal IS.

Here, the detection target waveform learned by the target waveform detection algorithm AL is called the detection target waveform TW. The detection target waveform TW may include a normal detection target waveform and an abnormal detection target waveform. The target waveform detection algorithm AL may learn the normal detection target waveform and the abnormal detection target waveform. The expected detection target waveform generated by inputting an input waveform into the target waveform detection algorithm AL is called the detection target waveform DW.

The target waveform detection algorithm AL is an algorithm based on AI (Artificial Intelligence) or an algorithm based on a statistical method, etc. In AI-based algorithms, for example, models of neural networks that have learned the characteristics of detection target waveform TWs are used. The target waveform detection algorithm AL will be described later.

The detection target waveform generation unit TDT generates detection target waveform DW by using the input signal IS and the target waveform detection algorithm AL. Specifically, detection target waveform generation unit TDT generates a detection target waveform DW by inputting an input waveform contained in the input signal into the target waveform detection algorithm AL, and outputs the generated detection target waveform DW. The detection target waveform generation unit TDT outputs the generated detection target waveform DW to the detection target waveform determination/abnormality detection unit TGDT. The detection target waveform generation unit TDT and the target waveform detection algorithm AL are input a signal input notification SI from signal input unit IIF as a trigger signal to start generating detection target waveform DW.

The detection target waveform determination/abnormality detection unit TGDT compares detection target waveform DW output by the detection target waveform generation unit TDT with the input waveform included in the input signal IS, and determines whether the input waveform corresponds to the detection target waveform TW. For example, the detection target waveform determination/abnormality detection unit TGDT uses the likelihood between the detection target waveform DW and the input waveform to determine whether the input waveform corresponds to the detection target waveform TW. The likelihood is a measure of plausibility. The greater the likelihood, the more detection target waveform DWs and incoming waveforms can be called the same waveforms. The likelihood may be calculated using the Euclidean distance. In that case, the smaller the Euclidean distance, the greater the likelihood.

The detection target waveform determination/abnormality detection unit TGDT calculates the likelihood by comparing the detection target waveform DW with the input waveform. The detection target waveform determination/abnormality detection unit TGDT determines whether the input waveform corresponds to the detection target waveform TW or not based on the calculated likelihood value. For example, the detection target waveform determination/abnormality detection unit TGDT determines that the input waveform corresponds to the detection target waveform TW when the calculated likelihood is greater than the predetermined first threshold value set.

If the input waveform is determined to corresponds to the detection target waveform TW based on the calculated likelihood value, the detection target waveform determination/abnormality detection unit TGDT compares the input waveform determined to corresponds to the detection target waveform TW with the detection target waveform DW. Thus, the detection target waveform determination/abnormality detection unit TGDT determines whether the input waveforms are normal or abnormal.

For example, the detection target waveform determination/abnormality detection unit TGDT compares the detection target waveform DW with the input waveform to calculate the likelihood. The calculated likelihood value determines whether the input waveform is normal or abnormal. For example, the detection target waveform determination/abnormality detection unit TGDT determines that the input waveform is normal when the likelihood is greater than the predetermined second threshold value. Here, the first threshold value of the likelihood in determining whether it is the detection target waveform TW is smaller than the second threshold value of the likelihood in determining whether it is normal or abnormal. The detection target waveform determination/abnormality detection unit TGDT outputs the output signal OUT that is the determination result. For example, when the input waveform is determined to be normal, it indicates that the detection target apparatus is operating normally. Further, for example, when the input waveform is determined to be abnormal, it indicates that the detection target is an abnormal state.

Next, as the operation of the abnormality detection system of the present embodiment, the detection target waveform generation unit TDT, and the detection target waveform determination/abnormality detection unit TGDT will be described.

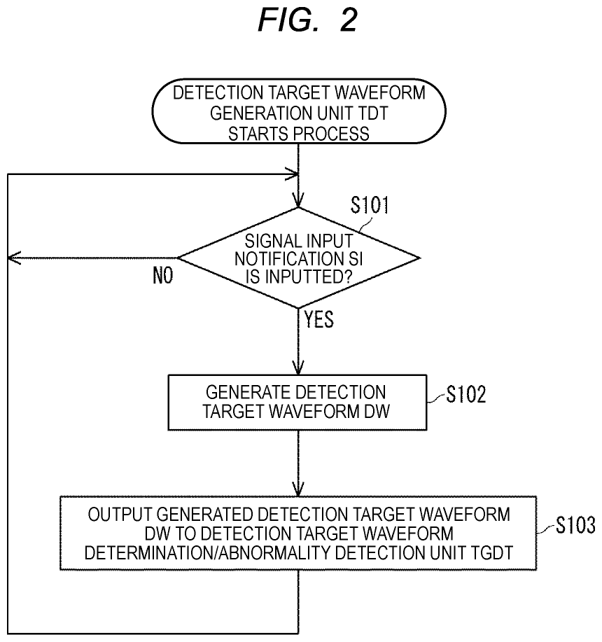

FIG. 2 is a flow chart illustrating the processes of the detection target waveform generation unit TDT in the abnormality detection system 1 according to first embodiment.

As shown in the step S101 of FIG. 2, the detection target waveform generation unit TDT first determines whether the signal input notification SI is input from the signal input unit IIF. When the signal input notification SI is not input, the detection target waveform generation unit TDT repeats the step S101 and continues to wait for the signal input notification SI to be notified from signal input unit IIF.

In the step S101, when the signal input notification SI is input from signal input unit IIF, the detection target waveform generation unit TDT generates the detection target waveform DW to be compared with the input waveform included in the input signal IS, as shown in the step S102.

Next, as shown in the step S103, the detection target waveform generation unit TDT outputs the generated detection target waveform DW to the detection target waveform determination/abnormality detection unit TGDT. Then, the process shifts to step S101, and the process is repeated. The process is terminated by a predetermined termination signal. Also, in the following flow chart, by a predetermined end signal, it is similar to finish the processing.

Although not shown, it may include receiving the monitor signal MS from the sensing target at the signal input unit IIF, and holding the received monitor signal MS in the input signal buffer IBF for a predetermined period of time, and outputting as the input signal IS including the input waveform.

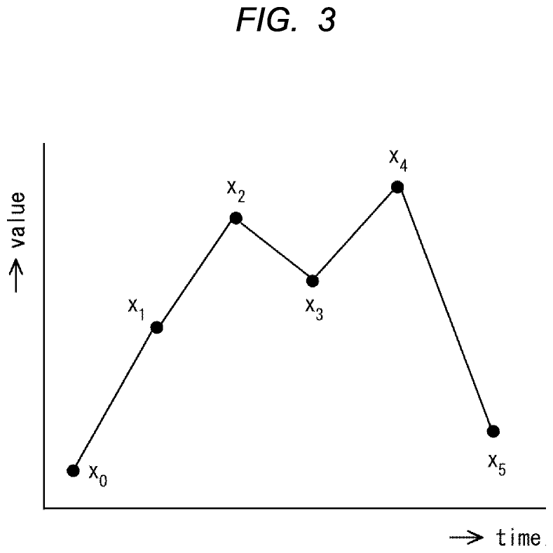

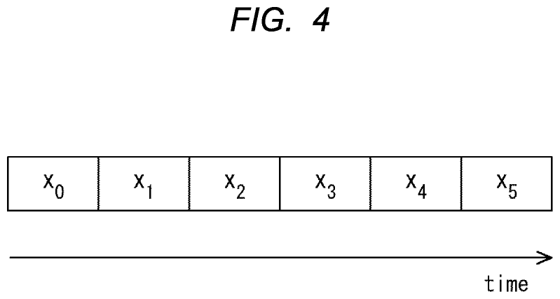

Here, as a means for generating the detection target waveform DW in the step S102, for example, the detection target waveform generation unit TDT may output the detection target waveform TW learned by the target waveform detection algorithm AL as a detection target waveform DW. Specifically, the target waveform detection algorithm AL holds time series data of detection target waveform TW. Then, the detection target waveform generation unit TDT may output the time series data. FIG. 3 is a diagram illustrating the detection target waveform TW in the abnormality detection system 1 according to the first embodiment, in which the horizontal axis represents time and the vertical axis represents value. FIG. 4 is a diagram illustrating an example of data of the detection target waveform TW in the abnormality detection system 1 according to the first embodiment.

If the detection target waveform TW is the waveform shown in FIG. 3, the target waveform detection algorithm AL holds time series data of detection target waveform TW itself, as shown in FIG. 4. If detection target waveform TW can be identified, such a technique is valid. In this case, it is not necessary to use the input signal IS.

Deep learning can also be used as an exemplary means of generating the detection target waveform DW in step S102. For example, the target waveform detection algorithm AL may, in advance, learns detection target waveform TW by an autoencoder using a neutral network. The detection target waveform TW may be labeled as normal detection target waveform TW or abnormal detection target waveform TW. Then, the target waveform detection algorithm AL that has learned detection target waveform TW may generate the detection target waveform DW by using the input waveform that has been input.

If the detection target waveform TW is learned by using an autoencoder, which is one of the techniques for deep learning, the detection target waveform DW can be generated even when there are several detection target waveform TWs with variations. That is, if an input waveform similar to one of detection target waveform TWs is input, the detection target waveform DW expected from the similar detection target waveform TWs can be generated.

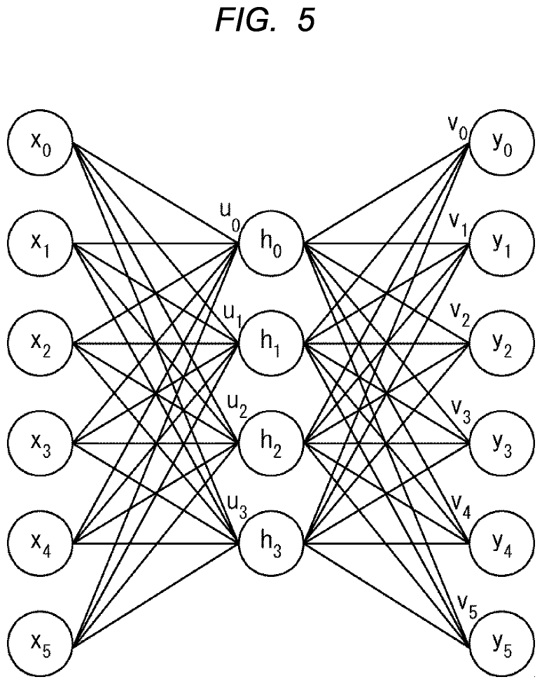

FIG. 5 is a diagram illustrating a perceptron representing the configuration of an autoencoder that is one of the techniques of deep learning used by the detection target waveform generation unit TDT in the abnormality detection system of the present embodiment. As shown in FIG. 5, the detection target waveform generation unit TDT may generate the detection target waveform DW using an autoencoder, which is one of the techniques of deep learning.

As shown in FIG. 5, x₀ to x₅ indicate the input nodes of the deep learning model, and y₀ to y₅ indicate the output nodes. In FIG. 5, h₀ to h₃ indicate the hidden nodes where the intermediate results of deep learning calculation are stored. In addition, in order to illustrate the calculation process of calculating the hidden nodes of h₀ to h₃ from the input nodes of x₀ to x₅, u₀ to u₃ are defined here. The autoencoder uses the value acquired at predetermined intervals along the time series of the input waveform as the input node. The autoencoder has the same number of output nodes as the number of input nodes. In addition, the autoencoder has a hierarchy that includes fewer hidden nodes than input and output nodes. The number of nodes in each layer shown in FIG. 5 is an example, and the present invention is not limited to this.

For example, when the input signal IS input from the input signal buffer IBF is a time-series signal of FIG. 3, the signals are input to the input nodes of x₀ to x₅ in time-series order.

As shown below, u₃ to u₀ can be calculated by equation (1). Furthermore, h₀ to h₃ can be computed using the activation functions of equation (2). However, there are many types of activation functions, and this is not the case. The designer of the deep learning selects one of the activation functions at the time of model design. In addition, v₀ to v₅ can be calculated by equation (3). Then, y₀ to y₅ can be calculated using activation functions, similar to the calculation of h₃ to h₀.

$$\begin{matrix}[ \begin{matrix}{u}_{0} \\ {u}_{1} \\ {u}_{2} \\ {u}_{3}\end{matrix} ] = [ \begin{matrix}{W}_{100} & ⋯ & {W}_{105} \\ ⋮ & ⋱ & ⋮ \\ {W}_{130} & ⋯ & {W}_{135}\end{matrix} ] [ \begin{matrix}{X}_{0} \\ {X}_{1} \\ {X}_{2} \\ {X}_{3} \\ {X}_{4} \\ {X}_{5}\end{matrix} ] + [ \begin{matrix}{b}_{10} \\ {b}_{11} \\ {b}_{12} \\ {b}_{13}\end{matrix} ] & Equation ( 1 ) \\ \begin{matrix}{h}_{n} = f ( {u}_{n} ) \\ n : 0 \sim 3\end{matrix} \{ \begin{matrix}sigmoid function \\ f ( {u}_{n} ) = \frac{1}{1 + {e}^{- {u}_{n}}} \\ hyperbolic function \\ f ( {u}_{n} ) = tanh ( {u}_{n} ) \\ ReLU \\ f ( {u}_{n} ) = max ( 0 , {u}_{n} ) \\ no use of functions \\ f ( {u}_{n} ) = {u}_{n}\end{matrix} & Equation ( 2 ) \\ [ \begin{matrix}{V}_{0} \\ {V}_{1} \\ {V}_{2} \\ {V}_{3} \\ {V}_{4} \\ {V}_{5}\end{matrix} ] = [ \begin{matrix}{W}_{200} & ⋯ & {W}_{203} \\ ⋮ & ⋱ & ⋮ \\ {W}_{250} & ⋯ & {W}_{253}\end{matrix} ] [ \begin{matrix}{h}_{0} \\ {h}_{1} \\ {h}_{2} \\ {h}_{3}\end{matrix} ] + [ \begin{matrix}{b}_{20} \\ {b}_{21} \\ {b}_{22} \\ {b}_{23} \\ {b}_{24} \\ {b}_{25}\end{matrix} ] & Equation ( 3 ) \\ \begin{matrix}{y}_{n} = f ( {v}_{n} ) \\ n : 0 \sim 5\end{matrix} \{ \begin{matrix}sigmoid function \\ f ( {v}_{n} ) = \frac{1}{1 + {e}^{- {v}_{n}}} \\ hyperbolic function \\ f ( {v}_{n} ) = tanh ( {v}_{n} ) \\ ReLU \\ f ( {v}_{n} ) = max ( 0 , {v}_{n} ) \\ no use of functions \\ f ( {v}_{n} ) = {v}_{n}\end{matrix} & Equation ( 4 )\end{matrix}$$

“W” and “b” in the equations (1) and (3) represent weights and biases, respectively, and are values obtained by learning results. In autoencoder learning, the values of weight W and bias b are adjusted so that xₙ of input nodes and yₙ of output nodes are the same. In this instance, the value to be set to the input node xₙ is the detection target waveform TW data. If there is more than one detection target waveform TW data to be learned, the values of the weight W and bias b are adjusted so that the input node xₙ and output node yₙ will be the same value for any of data of the detection target waveform TW. This makes it possible to learn a plurality of types of the detection target waveform TW.

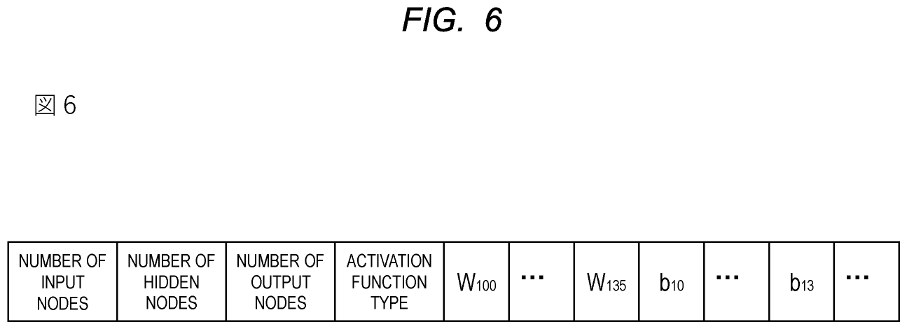

FIG. 6 is a diagram illustrating a learning data for deep learning that is set to the target waveform detection algorithm AL in the abnormality detection system 1 according to the first embodiment. As shown in FIG. 6, the target waveform detection algorithm AL when the detection target waveform generation unit by deep learning is used includes the information that indicates the components of deep learning. In this way, the detection target waveform generation unit TDT generates the detection target waveform DW by inputting an input waveform to the target waveform detection algorithm AL that has learned the detection target waveform TW, and outputs the generated detection target waveform DW.

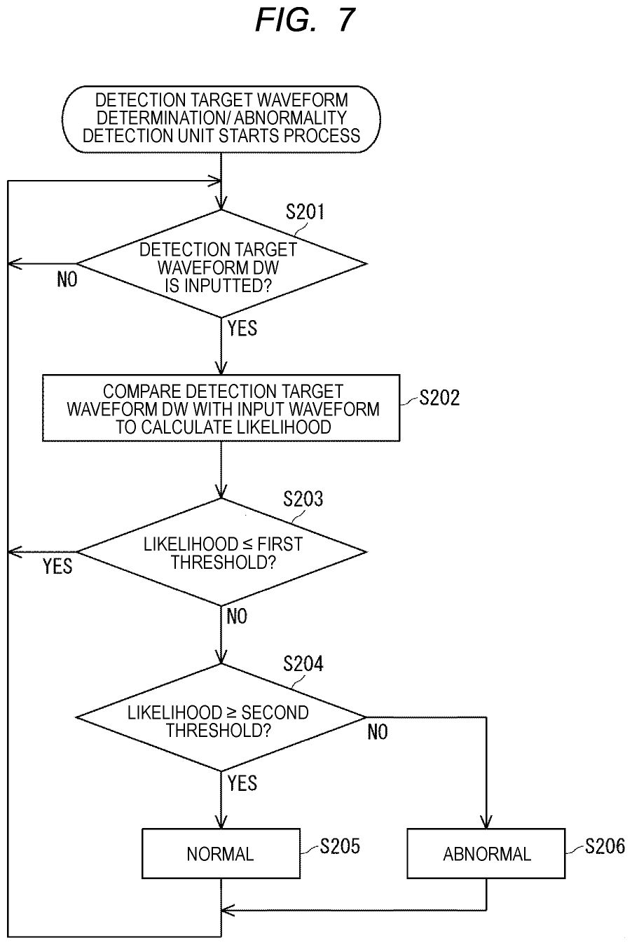

FIG. 7 is a flow chart illustrating the processes of the detection target waveform determination/anomaly detection unit TGDT in the abnormality detection system 1 according to the first embodiment. As shown in the step S201 of FIG. 7, the detection target waveform determination/abnormality detection unit TGDT determines whether the detection target waveform DW is input from the detection target waveform generation unit TDT. If the detection target waveform DW is not input, the detection target waveform detection/abnormality detection unit TGDT repeats the step S201 and continues to wait for the detection target waveform DW to be input from the detection target waveform generation unit TDT.

In step S201, when the detection target waveform DW is input from the detection target waveform generation unit TDT, the detection target waveform determination/abnormality detection unit TGDT calculates the likelihood by comparing the detection target waveform DW with the input waveform in the input signal IS, as shown in step S202.

Next, as shown in the step S203, the detection target waveform determination/abnormality detection unit TGDT determines whether the calculated likelihood is equal to or less than the detection target determination threshold (first threshold). The likelihood is significantly lower when the input waveforms at the input signal IS differ completely from the detection target waveform DW. Therefore, the likelihood is equal to or less than the detection target determination threshold. In this instance, abnormality detection is not performed, and the process shifts to the step S201. The value of first threshold for determining that the likelihood is significantly lower is set in advance in accordance with the likelihood of the waveform to be detected. In this way, the detection target waveform determination/abnormality detection unit TGDT compares the generated detection target waveform DW with the input waveform to determine whether the input waveform corresponds to the detection target waveform TW.

In the step S203, when the likelihood is greater than the detection target determination threshold (first threshold) and the input waveform included in the input signal IS is determined to correspond to detection target waveform TW, it is further determined whether the likelihood is the abnormality determination threshold (second threshold) or more, as shown in the step S204. The determination criterion of normal or abnormal can be arbitrarily determined based on the set value of the second threshold.

In the step S204, when the likelihood is equal to or greater than the second threshold value, it is determined as a normal detection target waveform TW as shown in the step S205. On the other hand, for example, when abnormal noise is superimposed on the input waveform, the likelihood is smaller than the second threshold. In such cases, it is determined as an abnormal detection target waveform, as shown in the step S206.

In this case, the detection target waveform determination/abnormality detection unit TGDT compares the input waveform determined to correspond to the detection target waveform TW with the detection target waveform DW to determine whether the input waveform is normal or abnormal. When determining whether the input waveform corresponds to the detection target waveform TW or whether the input waveform determined to correspond to detection target waveform is normal or abnormal, the detection target waveform determination/abnormality detection unit TGDT determines based on the likelihood calculated by comparing the detection target waveform DW with the input waveform. The first threshold of the likelihood at the time of determining whether the input waveform corresponds to the detection target waveform TW is set to be smaller than the second threshold of the likelihood at the time of determining whether the detection target waveform TW is normal or abnormal.

Next, as a likelihood calculation method in the detection target waveform determination/abnormality detection unit TGDT, an operation example when the Euclidean distance is used will be described. When the Euclidean distance is used, the closer the calculation result is to 0, the higher the likelihood is.

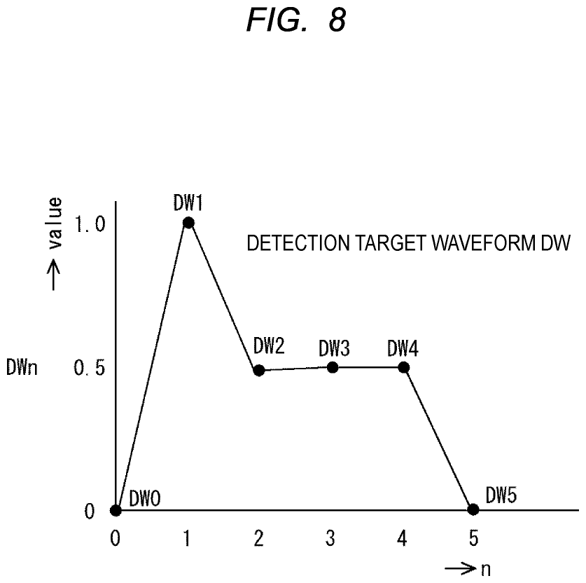

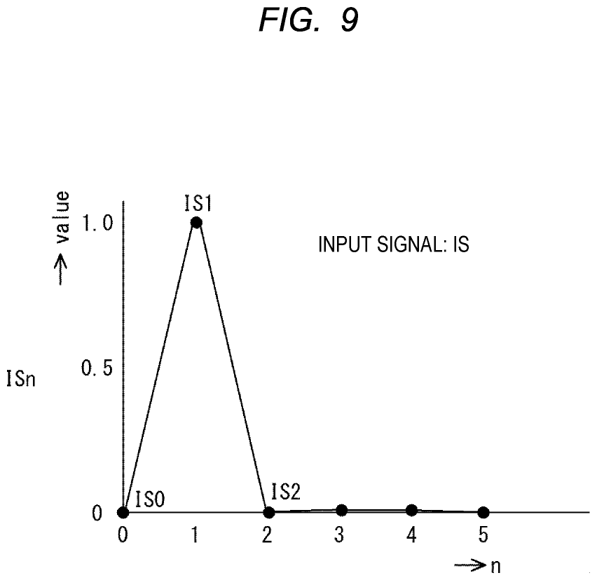

FIG. 8 is a diagram illustrating the detection target waveform input to the detection target waveform determination/abnormality detection unit TGDT in the abnormality detection system 1 according to first embodiment. The horizontal axis indicates the output nodes, and the vertical axis indicates the value. FIG. 9 is a diagram illustrating an input signal IS including an input waveform that is not detection target waveform and is input to the detection target waveform determination/abnormality detection unit TGDT in the abnormality detection system 1 according to first embodiment. The horizontal axis indicates the output nodes, and the vertical axis indicates the value.

As shown in FIG. 8, it is assumed that the detection target waveform DW is input to the detection target waveform detection/abnormality detection unit TGDT. In this case, as shown in FIG. 9, when the input signal IS including the input waveform that is not the detection target is input to the detection target waveform detection/abnormality detection unit TGDT, the likelihood u due to the Euclidean distance can be expressed by the following equation (5).

$$u = {\sum }_{n = 0}^{5} {( {DW}_{n} - {IS}_{n} )}^{2} \qquad Equation ( 5 )$$

DW0 to DW5 of detection target waveform DW in FIG. 8 are DW0=0, DW1=1.0, DW2=0.5, DW3=0.5, DW4=0.5, and DW5=0, respectively. IS0 to IS5 of the input signal IS of FIG. 9, are respectively, IS0=0, IS1=1.0, IS2=0, IS3=0, IS4=0, IS5=0. Then, the likelihood u is “0.75”. In the step S203 of FIG. 7, if the threshold value for determining that the likelihood is significantly low is “0.5”, the input signal IS shown in FIG. 9 is determined not to correspond to the detection target waveform TW (when using the Euclidean distance, the closer the calculated result is to “0”, the higher the likelihood).

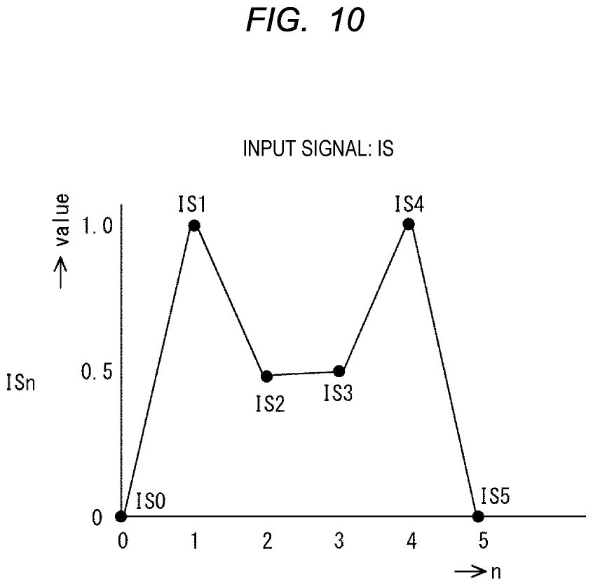

FIG. 10 is a diagram illustrating an input signal IS that resembles a detection target waveform DW but includes input waveforms with some disturbances in abnormality detection system according to first embodiment, with the horizontal axis representing the output nodes and the vertical axis representing the values. As shown in FIG. 10, IS0 to IS5 of the input signal IS are IS0=0, IS1=1.0, IS2=0.5, IS3=0.5, IS4=1.0, IS5=0, respectively. Then, the likelihood u is “0.25”. In the step S203 of FIG. 7, the threshold for determining that the likelihood is significantly lower is “0.5”. For this reason, the input signal IS of FIG. 10 is identified as a detection target waveform TW. In step 204 of FIG. 7, if the second threshold value for determining normal or abnormal is “0.1”, the input signal IS of FIG. 10 will ultimately be determined to be an abnormal detection target waveform TW.

For example, as the input signal IS, when a signal similar to the detection target waveform DW shown in FIG. 8 is input, the likelihood u is a value close to “0”. As a result, it is determined that the input signal corresponds to the normal detection target waveform TW.

Next, effects of the present embodiment will be described. In the abnormality detection system 1 of the present embodiment, by inputting the input waveform to the target waveform detection algorithm AL, the detection target waveform DW is generated, and then, by comparing the input waveform with the detection target waveform DW, it is determined whether the input waveform corresponds to the detection target waveform TW. Thus, by using the detection target waveform DW focusing on the features of the detection target waveform TW, the features of the input waveform can be compared with the features of the detection target waveform TW. Therefore, it is possible to neglect the difference in the portion, which is not the feature point, and to emphasize the comparison of the feature points. Thus, in addition to the detection target waveform to be detected, even when waveforms satisfying the conditions for separating the detection target are mixed, it is possible to improve the accuracy of recognizing the original detection target waveform TW.

By comparing the input waveform determined to correspond to the detection target waveform TW with the detection target waveform DW, it is determined whether the input waveform is abnormal or normal. This improves the accuracy of detecting abnormalities in detection target waveform TWs.

The target waveform detection algorithm AL, for example, learns the detection target waveform TWs by autoencoders using a neutral network. Therefore, even if there are a plurality of types of the detection target waveform TW, such as there is a variation in detection target waveform TW, if the input waveform having the features of any of types of the detection target waveform TW is input, it is possible to generate a detection target waveform DW similar thereto.

The autoencoder has a hierarchy that includes fewer hidden nodes than input and output nodes. Therefore, the features of the input waveform can be extracted by the hidden node having fewer nodes, and the accuracy of recognizing the original detection target waveform of the input waveform can be improved. If time series data of the detection target waveform TW is output as the detection target waveform DW, the detection target waveform TW can be specified and the accuracy of the recognition for the specified detection target waveform TW can be improved.

By using the likelihood to determine whether the input waveform corresponds to the detection target waveform TW or whether detection target waveform TW is normal or abnormal, the degree of similarity between the detection target waveform TW and the input waveform can be quantified.

By holding the monitor signal MS for a predetermined period of time in the input signal buffer IBF, the input signal IS including the input waveform can be formed. Therefore, the input waveform to be detected can be output to the detection target waveform generation unit TDT and the same input waveform can be output to the detection target waveform determination/abnormality detection unit TGDT.

### Second Embodiment

Next, the abnormality detection system according to the second embodiment will be described. In the above-described first embodiment, each time the signal input IS is input, the detection determination of detection target waveform and the abnormality detection are performed. In the present embodiment, only the detection of a part of the detection target waveform is performed each time the signal input IS is input, then the abnormality detection of the entire waveform is performed after the detection of a part of the waveform is performed.

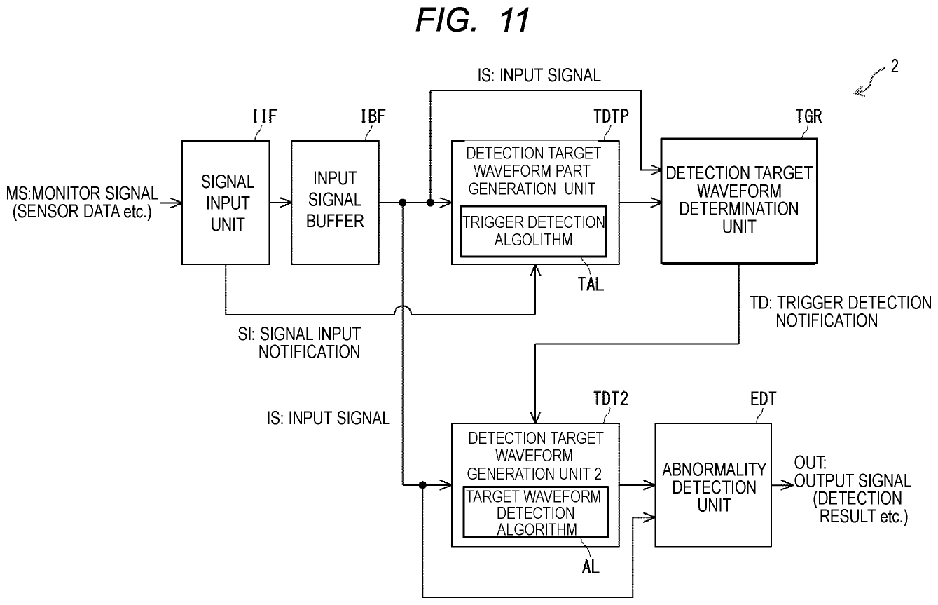

FIG. 11 is a block diagram illustrating the abnormality detection system 2 according to the second embodiment. As shown in FIG. 11, the abnormality detection system 2 of the present embodiment includes a signal input unit IIF, an input signal buffer IBF, a detection target waveform part generation unit TDTP, an detection target waveform determination unit TGR, an detection target waveform generation unit TDT2, and an abnormality detection unit EDT.

The detection target waveform part generation unit TDTP comprises a trigger detection algorithm TAL. The trigger detection algorithm TAL is constructed by learning the detection target waveform TW, for example. The trigger detection algorithm TAL generates at least a part of detection target waveform DW by inputting an input waveform contained in the input signal IS. Then, detection target waveform part generation unit TDTP outputs a part of the generated detection target waveform DW to the detection target waveform determination unit TGR. In addition, the detection target waveform part generation unit TDTP is input a signal input notification SI from the signal input unit IIF as a trigger signal that starts generating at least a part of detection target waveform DW. Incidentally, the configuration and operation of the detection target waveform part generation unit TDTP shown in FIG. 11 is the same as the detection target waveform generation unit TDT shown in FIG. 1, except for using the trigger detection algorithm and for generating a part of the detection target waveform DW.

The detection target waveform determination unit TGR compares a part of the input waveform included in the input signal IS with a part of the detection target waveform DW generated by detection target waveform part generation unit TDTP, and determines whether a part of the input waveform corresponds to a part of the detection target waveform TW. For example, the detection target waveform determination unit TGR calculates the likelihood between a part of the detection target waveform DW and a part of the input waveform, and determines whether a part of the input waveform corresponds to the part of the detection target waveform TW by the value of the calculated likelihood. Specifically, the detection target waveform determination unit TGR determines that a part of the input waveforms corresponds to a part of the detection target waveform TW when the calculated likelihood value is greater than the third threshold value. When it is determined that a part of the input waveform corresponds to a part of detection target waveform TW, the detection target waveform determination unit TGR transmits a trigger detection notification TD to the detection target waveform generation unit TDT2.

The detection target waveform generation unit TDT2 has the target waveform detection algorithm AL. The target waveform detection algorithm AL is constructed by learning the detection target waveform TW, for example. The target waveform detection algorithm AL generates a detection target waveform DW by inputting an input waveform contained in the input signal IS. The detection target waveform generation unit TDT2 outputs the generated detection target waveform DW to the abnormality detection unit EDT. The detection target waveform generation unit TDT2 receives the trigger detection notification TD from the detection target waveform detection determination unit TGR as a trigger signal for starting generation of the detection target waveform DW.

The abnormality detection unit EDT compares the detection target waveform DW with the input waveform, which is determined to correspond to a part of the detection target waveform TW, and determines whether the input waveform is normal or abnormal. For example, the abnormality detection unit EDT calculates the likelihood by comparing the detection target waveform DW with the input waveform, and determines whether the input waveform is normal or abnormal by the value of the calculated likelihood. For example, the abnormality detection unit EDT determines that the input waveform is normal, when the calculated likelihood is greater than the predetermined fourth threshold set. Here, the third threshold of the likelihood when determining whether the input waveform corresponds to a part of the detection target waveform TW is smaller than the fourth threshold of the likelihood when determining whether the input waveform is normal or abnormal.

The abnormality detection unit EDT may determine whether the input waveform corresponds to the detection target waveform TW or not prior to determining whether the input waveform is normal or abnormal. For example, the abnormality detection unit EDT may determine the input waveform as detection target waveform when the value of the calculated likelihood is greater than the predetermined first threshold.

Next, as the operation of according to the abnormality detection system 2 of the present embodiment, the processes of the detection target waveform determination unit TGR, the detection target waveform generation unit TDT2 and the abnormality detection unit EDT will be described.

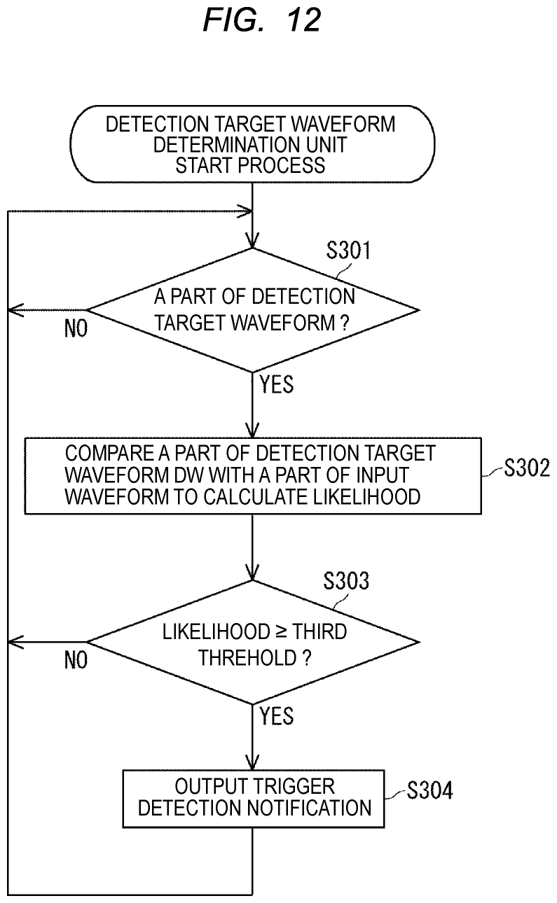

FIG. 12 is a flow chart illustrating the processes of the detection target waveform determination unit in the abnormality detection system according to second embodiment. As shown in the step S301 of FIG. 12, the detection target waveform determination unit TGR first determines whether a part of detection target waveform DW is input from the detection target waveform part generation unit TDTP. If no part of detection target waveform DW is input, the step S301 is repeated until a part of detection target waveform DW is input.

In the step S301, when a part of detection target waveform DW is input, the detection target waveform determination unit TGR compares a part of detection target waveform with a part of the input waveform included in the input signal IS and calculates the likelihood as shown in the step S302.

Next, as shown in the step S303, the detection target waveform determination unit TGR determines whether the calculated likelihood exceeds the detection target determination threshold (the third threshold). If the calculated likelihood is low and the input signal does not include a part of detection target waveform, it transitions to step S301.

On the other hand, in the step S303, when the calculated likelihood is high and a part of the input waveform is determined to correspond to a part of detection target waveform TW, the trigger detection notification TD is transmitted to the detection target waveform generation unit TDT2 as shown in the step S304.

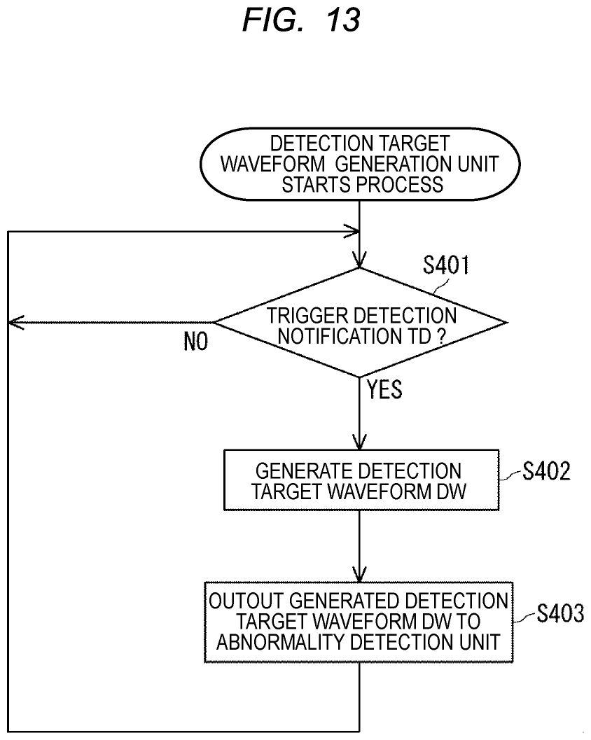

FIG. 13 is a flow chart illustrating the processes of the detection target waveform generation unit in the abnormality detection system according to second embodiment. As shown in the step S401 of FIG. 13, the detection target waveform generation unit TDT2 first determines whether the trigger detection notification TD is notified from the detection target waveform determination unit TGR. When the trigger detection notification TD is not notified from the detection target waveform determination unit TGR, the detection target waveform generation unit TDT2 repeats the step S401 and continues to wait until the trigger detection notification TD is notified.

In the step S401, when the trigger detection notification TD is notified, as shown in the step S402, the detection target waveform generation unit TDT2 generates the detection target waveform DW to be compared with the input waveform contained in the input signal. As a means for generating detection target waveform DW in the step S402, like detection target waveform generation unit TDT, for example, an autoencoder which is one of the deep learning methods may be used.

Next, as shown in the step S403, the detection target waveform generation unit TDT2 outputs the generated detection target waveform DW to the abnormality detection unit EDT and transits to the step S401.

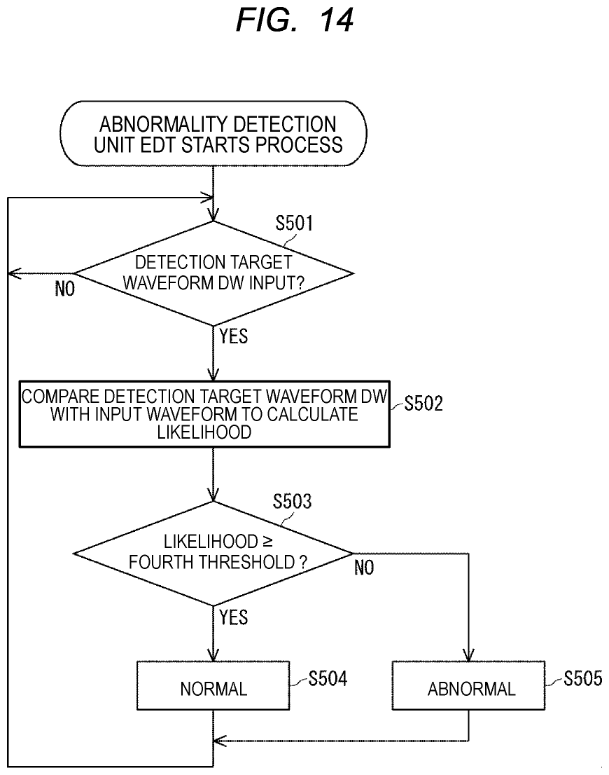

FIG. 14 is a flow chart illustrating the process content of the anomaly detection unit EDT in the abnormality detection system according to second embodiment. As shown in the step S501 of FIG. 14, the abnormality detection unit EDT determines whether the detection target waveform DW is the input from detection target waveform generation unit TDT2. If the detection target waveform DW is not input from the detection target waveform generation unit TDT2, the abnormality detection unit EDT repeats the step S501 and continues to wait until detection target waveform DW is input.

In the step S501, when the detection target waveform DW is input, the abnormality detection unit EDT compares the detection target waveform DW with the input waveform and calculates the likelihood as shown in the step S502. As a method of calculating the likelihood, for example, a Euclidean distance or the like is used.

Next, as shown in the step S503, the abnormality detection unit EDT determines whether the calculated likelihood is equal to or greater than the fourth threshold as the abnormality determination threshold. Thereby, the abnormality detection unit EDT determines whether the input waveform is normal or abnormal using the fourth threshold determined in advance for the calculated likelihood. The criterion for determination whether it is normal or abnormal can be arbitrarily determined based on the set value of the fourth threshold.

In the step S503, when the calculated likelihood is equal to or greater than the fourth threshold as the abnormality determination threshold, as shown in the step S504, it is determined that the input waveform is normal. On the other hand, in the step S503, when the calculated likelihood is smaller than the fourth threshold of the abnormality determination threshold, as shown in the step S505, the input waveform is determined to be abnormal. If the calculated likelihood is less than the fourth threshold, for example, when detection target waveform TW is multiplied by noise.

Next, effects of the present embodiment will be described. In the present embodiment, until it is determined whether or not the input waveform corresponds to the detection target waveform TW, only a part of the input waveform is targeted. That is, the detection target waveform part generation unit TDTP generates a part of detection target waveform DW. The detection target waveform determination unit TGR determines whether some of the input waveforms correspond to part of the detection target waveform TW. Therefore, the calculation load of the abnormality detection system 2 can be reduced.

In addition, the abnormality detection unit EDT determines whether the input waveform is abnormal or normal only when the input waveform is determined to be a part of detection target waveform TW. As a result, the calculation load of the abnormality detection system 2 can be reduced.

The trigger detection algorithm TAL and the target waveform detection algorithm AL shall have learned the detection target waveform TW by using an autoencoder using a neutral network. Thus, even if there are a plurality of types of detection target waveform TW, such as variations in detection target waveform TW, if an input waveform having features of any of types of detection target waveform TW is input, it is possible to generate a detection target waveform DW similar to the input waveform. Other configurations, operations, and effects are included in first embodiment description.

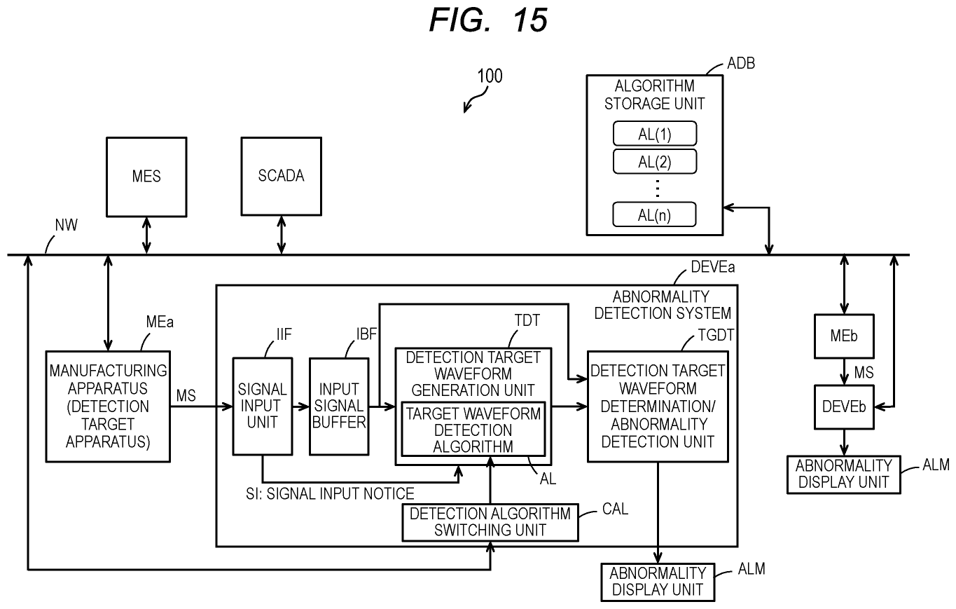

Next, a manufacturing system including a abnormality detection system according to third embodiment will be described. A manufacturing system is, for example, a semiconductor device manufacturing system. FIG. 15 is a block diagram illustrating a manufacturing system including a third embodiment abnormality detection system. As shown in FIG. 15, the manufacturing system 100 includes a plurality of abnormality detection systems DEVEa and DEVEb, a plurality of manufacturing apparatus MEa and MEb, an algorithm storage unit ADB, a MES (Manufacturing Execution System) and a SCADA (Supervisory Control And Data Acquisition), and a communication network NW that connects these abnormality detection systems. The fabrication devices MEa and MEb are devices to be sensed. Although the DEVEa and the DEVEb have been described as the abnormality detection system, three or more abnormality detection systems may be included. Although MEa and MEb have been shown as a manufacturing apparatus, more than two manufacturing apparatus may be included.

Each of the abnormality detection systems DEVEa and DEVEb has the same configuration as that of abnormality detection system 1 of first embodiment except for the addition of the detection algorithm switching unit CAL, and performs the same operation as that of the abnormality detection system 1.

SCADA is a monitoring device of the entire manufacturing system 100. MES is a manufacturing process control device. MES transmits manufacturing conditions of manufacturing apparatus MEa and MEb to communication networks NW when semiconductor device, e.g., a semiconductor wafer, is thrown into manufacturing apparatus MEa and MEb. In addition, the MES reads out the target waveform detection algorithm according to the manufacturing conditions of the manufacturing apparatus MEa and MEb from the algorithm storage unit ADB and transmits it to the detection algorithm switching unit CAL in the abnormality detection system DEVEa and DEVEb.

The manufacturing apparatus MEa and MEb process the semiconductor wafers based on manufacturing conditions from MES. The manufacturing apparatus MEa and MEb then outputs monitor signals MS representing the status of the process. Here, the manufacturing apparatus MEa and MEb output monitor signals MS to the abnormality detection systems DEVEa and DEVEb, respectively. Examples of device MEa and MEb include a plasma CVD (Chemical Vapor Deposition) device for performing a processing process associated with a film forming process, an exposure device for performing a processing process associated with a patterning process, and a plasma etching device for performing a processing process associated with an etching process.

The abnormaity detection systems DEVEa and DEVEb receive the monitor signals MS of the manufacturing apparatus MEa and MEb. The abnormality detection systems DEVEa and DEVEb perform abnormality detection in the same manner as in the abnormality detection system 1 of first embodiment. When an abnormality is detected by the detection target waveform determination/abnormality detection unit TGDT in the abnormality detection system DEVEa or DEVEb, an abnormality is notified to the abnormality display unit ALM.

The abnormality display unit ALM may be, for example, a light that illuminates at the time of an abnormality or may be a device that indicates that there is an abnormality on the monitor screen. Although not described in the present configuration example, the anomaly indicator ALM may be a mechanism to notify SCADA via the communication network NW.

In the actual operation, since the detection target also changes depending on the manufacturing condition of the manufacturing apparatus MEa and MEb, it is desirable to have a mechanism for changing the detection algorithm as described in FIG. 15 as the detection algorithm switching unit CAL.

Thus, the abnormality detection system DEVEa and DEVEb of the present embodiment includes a predetermined manufacturing apparatus MEa and manufacturing apparatus MEb, the algorithm storage unit ADB storing an target waveform detection algorithm AL1 according to the manufacturing conditions of the manufacturing apparatus MEa and an target waveform detection algorithm AL2 according to the manufacturing conditions of the manufacturing apparatus MEb. The input signals IS are input from the manufacturing apparatus MEa or the manufacturing apparatus MEb to be detected. The target waveform detection algorithm AL in the detection target waveform generation unit TDT can be switched to the target waveform detection algorithm AL1 or the target waveform detection algorithm AL2.

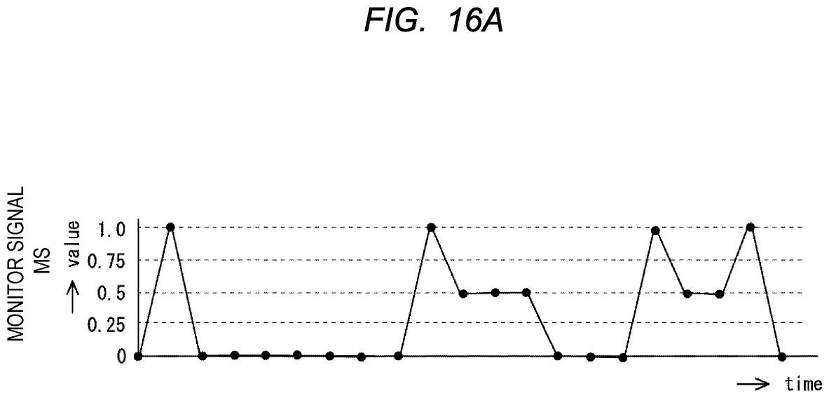

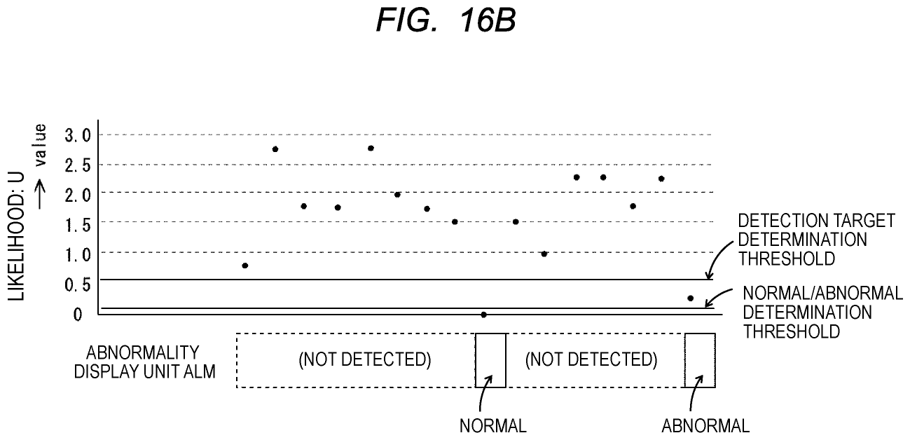

FIGS. 16A and 16B are timing charts illustrating the operations of the manufacturing systems according to third embodiment. FIG. 16A shows display monitor signals and FIG. 16B shows the likelihood and the abnormality display unit. As shown in FIG. 16A, the monitor signal MS is a signal input from the manufacturing apparatus MEa to the abnormality detection system DEVEa. In addition, as shown in FIG. 16B, the likelihood of detection target waveform determination/abnormality detection unit TGDT when the value of detection target waveform DW is directly set to the target waveform detection algorithm AL through the detection algorithm switching unit CAL is shown.

In the example of operation of the manufacturing system 100 of the present embodiment, the first threshold to determine the detection target waveform TW is defined “0.5”, only the waveforms to be detected are appropriately detected. Further, by setting the second threshold value of the normal abnormality determination to “0.1”, the determination of the normal or abnormality is also appropriately performed.

In the present embodiment, in the manufacturing system 100 including a plurality of manufacturing apparatus, a plurality of abnormality detection systems DEVEa and DEVEb are arranged in the respective manufacturing apparatus. Therefore, the monitor signal MS of each manufacturing apparatus is input, it is possible to detect abnormality based on the input waveforms specific to each manufacturing apparatus. In addition, the abnormality detection systems DEVEa and DEVEb can generate the detection target waveform DWs suitable for manufacturing apparatus by switching the target waveform detection algorithm at the algorithm storage unit ADB for each manufacturing method to be monitored. In addition to the detection target waveform TW to be detected, even when the waveform satisfying the condition for separating the detection object is mixed, recognizes the detection target waveform TW, further, it is possible to detect the abnormality of the detection target waveform TW. Other configurations, operations and effects are included in the descriptions of first and second embodiments.

Although each embodiment has been described above, the present invention is not limited to the above-described configuration, and various modifications can be made without departing from the technical concept. Also, abnormality detection systems combining the configurations of first embodiment to third embodiment are within the scope of the technical concept. The following methods for detecting abnormalities are also within the scope of the technical concept of the first embodiment to third embodiment. An abnormality detection program executed an abnormality detection method by a computer is also within the scope of the technical concept.

### (Supplementary Note 1)

An abnormality detection method comprising: inputting an input waveform included in an input signal to an target waveform detection algorithm which has learned detection target waveform to generate an expected detection target waveform; outputting the expected detection target waveform, and determining that the input waveform corresponds to the detection target waveform by comparing the expected detection target waveform with the input waveform.

### (Supplementary Note 2)

The abnormality detection method according to Supplementary note 1, wherein the method further comprises determining that the input waveform indicates normal or abnormal by comparing the input waveform which is determined to correspond to the detection target waveform with the expected detection target waveform.

### (Supplementary Note 3)

The abnormality detection method according to Supplementary note 2, wherein the target waveform detection algorithm learns the detection target waveform by autoencoder using neural network.

### (Supplementary Note 4)

The abnormality detection method according to Supplementary note 3, wherein the autoencoder includes a hierarchy in which input nodes receiving values acquired at predetermined intervals along the time series of the input waveforms, output nodes whose number is equal to a number of the input nodes, and hidden nodes whose number is less than those of the input nodes.

### (Supplementary Note 5)

The abnormality detection method according Supplementary note 2, wherein the determining that the input waveform corresponds to the detection target waveform and the determining that the input waveform indicates normal or abnormal each comprises determining based on a likelihood between the input waveform and the expected detection target waveform, wherein a first threshold of the likelihood in the determining that the input waveform corresponds to the detection target waveform is lower than a second threshold of the likelihood in the determining that the input waveform indicates normal or abnormal.

### (Supplementary Note 6)

The abnormality detection method according to Supplementary Note 5, wherein the likelihood is calculated by using Euclidean distance.

### (Supplementary Note 7)

The abnormality detection method according to Supplementary note 1, further comprising: receiving a monitor signal from a detection target; and holding the monitor signal for a predetermined period of time for forming the input signal including the input waveform, wherein the outputting the expected detection target waveform comprises receiving the input waveform, and the determining that the input waveform corresponds to the detection target waveform comprises comparing the input waveform.

What is claimed is:

1. An abnormality detection system, comprising:
a detection target waveform generation unit having an target waveform detection algorithm learning a detection target waveform, being configured to generate an expected detection target waveform by executing the target waveform detection algorithm for an input waveform included in an input signal, and being configured to output the expected detection target waveform;
a detection target waveform determination and abnormality detection unit configured to compare the expected detection target waveform with the input waveform and to determine that the input waveform corresponds to the detection target waveform.

2. The abnormality detection system according to claim 1,
wherein the detection target waveform determination and abnormality detection unit compares the input waveform determined to correspond to the detection target waveform with the expected detection target waveform to determine whether the input waveform is normal or abnormal.

3. The abnormality detection system according to claim 2,
wherein the target waveform detection algorithm is an autoencoder using a neural network.

4. The abnormality detection system according to claim 4,
wherein the autoencoder includes a plurality of input nodes, a plurality of output nodes whose number is the same as the number of the input nodes, and a plurality of hidden nodes whose number is lower than the number of the input nodes,
wherein a plurality of values obtained at a predetermined time interval along time series from the input waveform are input to the input nodes.

5. The abnormality detection system according to claim 1,
wherein the detection target waveform generation unit outputs the detection target waveform learnt by the target waveform detection algorithm as the expected detection target waveform.

6. The abnormality detection system according to claim 6,
wherein the detection target waveform determination and abnormality detection unit determines by using likelihood between the expected detection target waveform and the input waveform, determines whether the input waveform includes the detection target waveform by using a first threshold of the likelihood, and determines whether the input waveform is normal by using a second threshold of the likelihood, and
wherein the first threshold is lower than the second threshold.

7. The abnormality detection system according to claim 6,
wherein the likelihood is calculated based on Euclidean distance.

8. The abnormality detection system according to claim 1, further comprising:
a signal input unit configured to receive a monitor signal from a detection target, and
an input signal buffer configured to hold the monitor signal within a predetermined period from the signal input unit to output to the detection target waveform generation unit and the detection target waveform determination and abnormality detection unit as the input signal including the input waveform.

9. The abnormality detection system comprising:
a detection target waveform partial generation unit having an trigger detection algorithm which learnt a detection target waveform, being configured to generate a part of an expected detection target waveform by executing the trigger detection algorithm for an input waveform included in an input signal, and being configured to output the part of the expected detection target waveform;
a detection target waveform determination unit configured to compare the part of the expected detection target waveform with a part of the input waveform and to determine that the part of the input waveform corresponds to the part of the detection target waveform.

10. The abnormality detection system according to claim 9, further comprising:
a detection target waveform generation unit having an target waveform detection algorithm which learnt the detection target waveform, being configured to generate the expected detection target waveform by executing the target waveform detection algorithm for the input waveform having the part of the input waveform determined to corresponding to the part of the detection target waveform, and being configured to output the expected detection target waveform, and
an abnormality detection unit configured to compare the expected detection target waveform with the input waveform and to determine that the input waveform is normal or abnormal.

11. The abnormality detection system according to claim 10,
wherein the target waveform detection algorithm is autoencoder using a neural network.

12. The abnormality detection system according to claim 10,
wherein the detection target waveform determination unit and abnormality detection unit determine by using likelihood between the expected detection target waveform and the input waveform,
wherein the detection target waveform determination unit determines by using a third threshold of the likelihood,
wherein the abnormality detection unit determines by using a fourth threshold of the likelihood,
wherein the third threshold is lower than the fourth threshold.

13. The abnormality detection system according to claim 1, further comprising:
a first manufacturing apparatus and a second manufacturing apparatus,
an algorithm storage unit storing a first target waveform detection algorithm corresponding to a manufacturing condition of the first manufacturing apparatus and a second target waveform detection algorithm corresponding to a manufacturing condition of the second manufacturing apparatus,
wherein the input signal is provided from the first manufacturing apparatus or the second manufacturing apparatus which is a detection target apparatus, and
wherein the detection target waveform generation unit selects the first target waveform detection algorithm or the second target waveform detection algorithm.

14. A programmable storage medium storing an abnormality detection program to be operated on a computer, the program comprising the steps of:
generating an expected detection target waveform by executing a target waveform detection algorithm, which is learnt a detection target waveform, for the input waveform included in an input signal to output the expected detection target waveform, and
determining whether the input waveform includes the detection target waveform by comparing the expected detection target waveform with the input waveform.

15. The programmable storage medium according to claim 14,
wherein the program further comprises
determining whether the input waveform is normal or abnormal by comparing the input waveform determined to include the detection target waveform with the expected detection target waveform.

16. The programmable storage medium according to claim 15,
wherein the target waveform detection algorithm is an autoencoder using a neural network.

17. The programmable storage medium according to claim 16,
wherein the autoencoder includes a plurality of input nodes, a plurality of output nodes whose number is the same as the number of the input nodes, and a plurality of hidden nodes whose number is lower than the number of the input nodes,
wherein a plurality of values obtained at a predetermined time interval along time series from the input waveform are input to the input nodes.

18. The programmable storage medium according to claim 15,
wherein the determining whether the input waveform includes the detection target waveform based on a first threshold of a likelihood between the expected detection target waveform and the input waveform,
wherein the determining whether the input waveform is normal or abnormal based on a second threshold of the likelihood, and
wherein the first threshold is lower than the second threshold.

19. The programmable storage medium according to claim 18,
wherein the likelihood is calculated based on Euclidean distance.

20. The programmable storage medium according to claim 14,
wherein the program further comprises,
receiving a monitor signal from a detection target, and
holding the monitor signal within a predetermined period to output as the input signal including the input waveform.
